(19) United States
(12) Patent Application Publication
(10) Pub. No.: US 2017/0170369 A1
(43) Pub. Date: Jun. 15, 2017

(54) SURFACE MOUNTABLE LIGHT EMITTING DIODE DEVICES

(71) Applicant: Toshiba Corporation, Tokyo (JP)

(72) Inventors: Chih-Wei Chuang, Albany, CA (US); Chao-Kun Lin, San Jose, CA (US)

(21) Appl. No.: 14/966,659

(22) Filed: Dec. 11, 2015

(51) Int. Cl. H01L 33/50; H01L 33/30; H01L 33/32

(52) U.S. Cl. CPC H01L 33/50; H01L 33/32; H01L 33/30; H01L 2933/0016

(57) ABSTRACT

A surface-mountable light emitting diode (LED) assembly and a method for making the surface-mountable LED assembly is disclosed. In one embodiment, the surface-mountable LED assembly includes an LED comprising a first layer having a first conductivity type, a second layer having a second conductivity type, and a light emitting layer between the first layer and the second layer. A transparent substrate is bonded to the LED via a transparent bonding layer disposed between the transparent substrate and the LED. In one embodiment, the transparent substrate comprises an amorphous solid, such as glass.

### FIELD OF THE INVENTION

This invention generally relates to surface-mountable light emitting diode (LED) assemblies.

### BACKGROUND OF THE INVENTION

In general, fabrication of light emitting diodes (LEDs) begins with a semiconductor growth substrate, typically a group III-V compound such as gallium nitride (GaN), gallium arsenide (GaAs), gallium phosphide (GaP), indium phosphide (InP), and gallium arsenide phosphide (GaAsP). The semiconductor growth substrate may also be sapphire (Al₂O₃), silicon (Si) and silicon carbide (SiC) for group III-Nitride based LEDs, such as gallium nitride (GaN). Epitaxial semiconductor layers are grown on the semiconductor growth substrate to form the N-type and P-type semiconductor layers of the LED. A light emitting layer is formed between the N-type and P-type semiconductor layers of the LED.

The epitaxial layers may be formed by a number of developed processes including, for example, Liquid Phase Epitaxy (LPE), Molecular Beam Epitaxy (MBE), and Metal Organic Chemical Vapor Deposition (MOCVD). After the epitaxial semiconductor layers are formed, electrodes are coupled to the N-type and P-type semiconductor layers using known photolithography, etching, evaporation, and polishing processes. Individual LEDs are diced and mounted to a package with wire bonding. An encapsulant is deposited onto the LED and the LED is sealed with a protective lens, completing the LED assembly. When a voltage is applied to the electrodes, a current will flow between the contacts, causing photons to be emitted by the light emitting layer.

FIG. 1 shows a cross-sectional view of a conventional surface-mountable LED assembly 100. The LED comprises an N-type semiconductor layer 102, a P-type semiconductor layer 104, and a light emitting layer 106, that are grown on a growth substrate 110. An N-electrode 114 and a P-electrode 112 are formed on, electrically coupled to, the N-type semiconductor layer 102 and the P-type semiconductor layer 104, respectively, of the LED. By forming both N-electrode 114 and P-electrode 112 on a same side of the LED, the surface-mountable LED 100 is able to accomplish its namesake—it can be mounted to the surface of a package or submount, without the need for wire bonding. Thus, surface-mountable LEDs such as the one shown in FIG. 1 are especially suitable for wafer level chip-scale packaging (WLCSP) applications.

To effectively emit light from the surface-mountable LED assembly 100, growth substrate 110 must be transparent to allow the light emitted by the light emitting layer 106 to escape through the growth substrate 110. Moreover, growth substrate 110 must be mono-crystalline in order to grow high quality semiconductor layers comprising the LED. Given these constraints, for conventional surface-mountable LED assemblies the choice of growth substrate is extremely limited, typically comprising SiC or Al₂O₃. One of the biggest drawbacks of using SiC or Al₂O₃ as the growth substrate 110 for the surface mountable LED 100 is the high cost of such materials. Additionally, SiC and Al₂O₃ substrates are limited to 8″ in diameter, or smaller. Compared to opaque Si substrates which are typically 12″ in diameter, the number of LED devices that can be formed on transparent SiC or Al₂O₃ substrate is substantially limited, further increasing the cost of forming conventional surface-mountable LED assemblies.

There is, therefore, an unmet demand for improved surface-mountable LED assemblies having lower cost and/or expanded uses without sacrificing light output power or device performance.

### BRIEF DESCRIPTION OF THE INVENTION

In one embodiment, a surface-mountable light emitting diode (LED) assembly includes an LED comprising a first layer having a first conductivity type, a second layer having a second conductivity type, and a light emitting layer disposed between the first layer and the second layer. In one embodiment, the first layer is a P-type semiconductor material and the second layer is an N-type semiconductor material. In another embodiment, the first layer is an N-type semiconductor material and the second layer is a P-type semiconductor material. In one embodiment, the first layer and second layer comprise a group III-V compound. In one embodiment, the first layer and second layer comprise GaN. In other embodiments, the first layer and second layer may comprise AlGaN, InAlN, AlInGaN, GaAs, GaP, or InP.

The surface-mountable LED further includes a transparent substrate bonded to the LED via a transparent bonding layer disposed between the transparent substrate and the LED. In one embodiment, the transparent substrate and transparent bonding layer passes light wavelengths between 380 nm to 750 nm. In one embodiment, the transparent substrate and transparent bonding layer has a transmittance greater than 50% for light wavelengths between 380 nm to 750 nm. In one embodiment, the transparent substrate comprises an amorphous solid, such as glass. In one embodiment, the transparent substrate is monolithic, comprising a uniform material throughout. In one embodiment, the transparent substrate has a refractive index between 1.4 and 1.7 for light wavelengths between 380 nm to 750 nm. In one embodiment, the transparent bonding layer comprises a silicone-based material. In other embodiments, the transparent bonding layer may comprise an epoxy-based material or spin-on-glass (SOG). In one embodiment, the transparent bonding layer has a refractive index between 1.4 and 1.7 for light wavelengths between 380 nm to 750 nm. In one embodiment, the surface of the first layer adjacent the transparent bonding layer is roughened.

The surface-mountable LED further includes a first electrode and a second electrode. The first electrode is formed on a surface of the first layer opposite the transparent substrate. The first electrode is electrically coupled to the first layer. The second electrode is formed on a surface of the second layer opposite the transparent substrate. The second electrode is electrically coupled to the second layer. In one embodiment, the first and second electrodes comprise a material having a high degree of optical reflectivity, such as Al, Au, Rh, and/or Ag.

In one embodiment, the surface-mountable LED further includes a layer doped with a light wavelength-converting material disposed over a surface of the transparent substrate opposite the LED. In one embodiment, the layer comprises silicone. In one embodiment, the light wavelength-converting material comprises phosphor particles. In other embodiments, the light wavelength-converting material comprises quantum dots or nanostructures, such as nanowires. In another embodiment, the transparent substrate is doped with the light-wavelength converting material. In yet a further embodiment, the transparent bonding layer is doped with the light-wavelength converting material.

In one embodiment, a method for forming a surface-mountable LED assembly includes providing a growth substrate and forming an LED comprising a first layer having a first conductivity type, a second layer having a second conductivity type, and a light emitting layer between the first layer and second layer, on a surface of the growth substrate. In one embodiment, the first layer is a P-type semiconductor material and the second layer is an N-type semiconductor material. In another embodiment, the first layer is an N-type semiconductor material and the second layer is a P-type semiconductor material. In one embodiment, the first layer and second layer comprise a group III-V compound. In one embodiment, the first layer and second layer comprise GaN. In other embodiments, the first layer and second layer comprise AlGaN, InAlN, AlInGaN, GaAs, GaP, or InP.

The method further includes forming a first electrode on a surface of the first layer, and electrically coupled to the first layer, and forming a second electrode on a surface of the second layer, and electrically coupled to the second layer. The first and second electrodes may be formed using known photolithography, etching, evaporation, and polishing processes. In one embodiment, the first and second electrodes comprise a material having a high degree of optical reflectivity, such as Al, Au, Rh, and/or Ag.

A temporary handling substrate is bonded to the LED via a temporary bonding layer between the temporary handling substrate and the LED. The method further includes removing the growth substrate and bonding a transparent handling substrate to the LED via a transparent bonding layer between the transparent substrate and the LED. In one embodiment, the growth substrate is removed using at least one of a chemical process, a mechanical process, and a laser-based process. In one embodiment, the growth substrate is removed using chemical etching. In other embodiments, the growth substrate is removed using mechanical grinding, laser lift-off (LLO), or any combination of processes.

In one embodiment, the transparent substrate and transparent bonding layer passes light wavelengths between 380 nm to 750 nm. In one embodiment, the transparent substrate and transparent bonding layer has a transmittance greater than 50% for light wavelengths between 380 nm to 750 nm. In one embodiment, the transparent substrate comprises an amorphous solid, such as glass. In one embodiment, the transparent substrate is monolithic, comprising a uniform material throughout. In one embodiment, the transparent substrate has a refractive index between 1.4 and 1.7 for light wavelengths between 380 nm and 750 nm. In one embodiment, the transparent bonding layer comprises a silicone-based material. In other embodiments, the transparent bonding layer may comprise an epoxy-based material or spin-on-glass (SOG). In one embodiment, the transparent bonding layer has a refractive index between 1.4 and 1.7 for light wavelengths between 380 nm and 750 nm. In one embodiment, the method further includes roughening a surface of the first layer adjacent the transparent bonding layer. In one embodiment, the surface of the first layer is roughened by chemical etching.

The method further includes removing the temporary handling substrate and temporary bonding layer. In one embodiment, the method further includes depositing a layer doped with a light wavelength-converting material over a surface of the transparent substrate opposite the LED. In one embodiment, the layer comprises silicone. In one embodiment, the light wavelength-converting material comprises phosphor particles. In other embodiments, the light wavelength-converting material comprises quantum dots or nanostructures, such as nanowires. In another embodiment, the method further includes doping the transparent substrate with the light-wavelength converting material. In yet a further embodiment, the method further includes doping the transparent bonding layer with the light-wavelength converting material.

### BRIEF DESCRIPTION OF THE FIGURES

FIG. 1 shows a cross-sectional view of a surface-mountable LED assembly.

FIG. 2 shows a cross-sectional view of a surface-mountable LED assembly, according to one embodiment of the invention.

FIG. 3 shows a cross-sectional view of a surface-mountable LED assembly, according to another embodiment of the invention.

FIG. 4 shows a cross-sectional view of a surface-mountable LED assembly, according to another embodiment of the invention.

FIG. 5 shows a cross-sectional view of a surface-mountable LED assembly, according to another embodiment of the invention.

FIG. 6A-6L shows cross-sectional views of the manufacturing steps for producing a surface-mountable LED assembly, according to one embodiment of the invention.

### DETAILED DESCRIPTION OF THE INVENTION

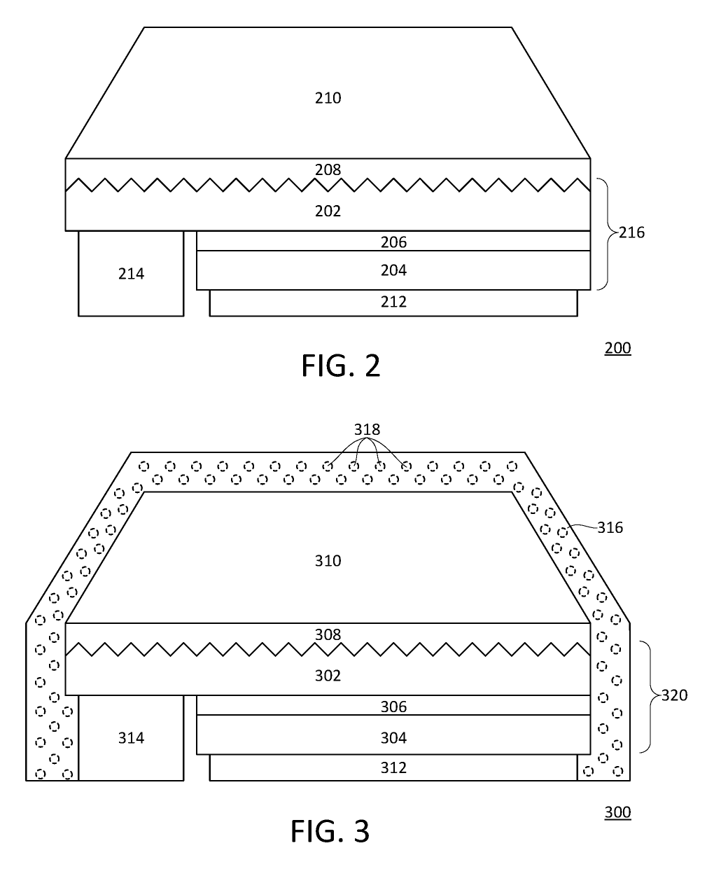

FIG. 2 shows a cross-sectional view of a surface-mountable LED assembly 200, according to one embodiment of the invention. As shown in FIG. 2, a light emitting layer 206 is disposed between a first semiconductor layer 202 and a second semiconductor layer 204. At least the first semiconductor layer 202, the second semiconductor layer 204, and the light emitting layer 206 comprise an LED 216. The first semiconductor layer 202 and the second semiconductor layer 204 may comprise any suitable semiconductor material, for example, group III-V compounds such as GaN, GaAs, GaP, InP, or GaAsP. In another embodiment, the first semiconductor layer 202 and the second semiconductor layer 204 may comprise a group III-Nitride compound, such as aluminum gallium nitride (AlGaN), indium gallium nitride (InGaN), or aluminum indium gallium nitride (AlGaInN). The first semiconductor layer 202 and the second semiconductor layer 204 may also comprise group II-VI compounds.

In one embodiment, the first semiconductor layer 202 comprises an N-type semiconductor material, and the second semiconductor layer 204 comprises a P-type semiconductor material. In another embodiment, the first semiconductor layer 202 comprises a P-type semiconductor material, and the second semiconductor layer 204 comprises an N-type semiconductor material. A first electrode 214 is formed adjacent a surface of the first semiconductor layer 202, and is electrically coupled to the first semiconductor layer 202. A second electrode 212 is formed adjacent a surface of the second semiconductor layer 204, and is electrically coupled to the second semiconductor layer 204.

Preferably, the first electrode 214 and the second electrode 212 comprise a material having a high degree of optical reflectivity to reflect the photons which are emitted from the light emitting layer 206 towards the first and second electrodes 214 and 212, respectively, so the photons have a greater chance of escaping the LED 216 as emitted light, improving the light output power and light extraction efficiency of the surface-mountable LED assembly 200. For example, the first and second electrodes 214 and 212 may comprise silver (Ag), aluminum (Al), rhodium (Rh), or gold (Au).

A transparent substrate 210 is bonded to the first semiconductor layer 202 of the LED via a transparent bonding layer 208. In one embodiment, the transparent substrate 210 and the transparent bonding layer 208 transmit visible light (typically having wavelengths between about 380 nm to 750 nm). In other embodiments, the transparent substrate 210 and the transparent bonding layer 208 transmit ultraviolet (UV) light (typically having wavelengths between 180 nm and 380 nm) or infrared (IR) light (typically having wavelengths greater than 750 nm). In various embodiments, the transparent substrate 210 and transparent bonding layer 208 has a transmittance greater than 50% for light wavelengths falling within the desired transmitted light spectrum (e.g. visible light, UV light, or IR light). In one embodiment, the transparent substrate 210 is monolithic, comprising a uniform material throughout.

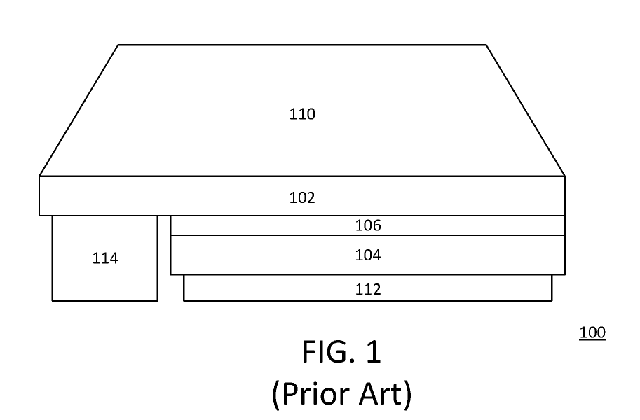

Because the first semiconductor layer 202 and the second semiconductor layer 204 are not grown on the transparent substrate 210, but rather bonded to the transparent substrate 210 via the transparent bonding layer 208, it is not necessary for the transparent substrate 210 to be mono-crystalline. The transparent substrate 210 may comprise an amorphous solid, such as glass. Compared to SiC and Al₂O₃ used for the growth substrate in conventional surface-mountable LED assemblies, such as the one shown in FIG. 1, glass is a relatively inexpensive material.

Moreover, because the first and second semiconductor layers 202 and 204 are bonded to the transparent substrate 210 via the transparent bonding layer 208, the first and second semiconductor layers 202 and 204 can be grown on any suitable growth substrate, not just a mono-crystalline substrate, such as SiC or Al₂O₃. This allows for greater flexibility when manufacturing the surface-mountable LED assembly 200. For example, the first and second semiconductor layers 202 and 204 may be grown on Si. Si wafers are widely available and relatively inexpensive, and typically larger (12″ in diameter) compared to SiC and Al₂O₃ wafers (usually 6″ or 8″ in diameter). More LEDs 216 can be formed on a 12″ wafer than an 8″ wafer (assuming of course, the size of each individual LED 216 die is similar), further reducing the cost of manufacturing the surface-mountable LED assembly 200.

The transparent bonding layer 208 may be any suitable material that is capable of bonding the transparent substrate 210 to the first semiconductor layer 202 of the LED 216. In one embodiment, the transparent bonding layer 208 comprises a silicone-based bonding material. In other embodiments, the transparent bonding layer 208 may comprise an epoxy-based bonding material or spin-on-glass (SOG).

As shown in FIG. 2, the surface of the first semiconductor layer 202 adjacent the transparent bonding layer 208 is roughened, forming projections having peaks and valleys. The projections reduces the amount of light that is reflected back into the LED 216 as a result of the transparent bonding layer 208 and the transparent substrate 210 having refractive indices that are lower than the refractive index of the first semiconductor layer 202. This phenomenon is known as total internal reflection, where the angle of incidence of the light is larger than the critical angle defined as Θ_{c}=arcsin (refractive index of a second medium/refractive index of the original medium).

In one embodiment, the transparent bonding layer 208 comprises a material having a refractive index between 1.4 and 1.7 for light wavelengths between 380 nm and 750 nm. In one embodiment, the transparent substrate 210 comprises a material having a refractive index between 1.4 and 1.7 for light wavelengths between 380 nm and 750 nm. The first and second semiconductor layers 202 and 204 of the LED 216 typically have refractive indices that are much higher than 1.7 for light wavelengths between 380 nm and 750 nm. For example, where the first and second semiconductor layers 202 and 204 comprise GaN, the refractive index of GaN is about 2.4 for light wavelengths between 380 nm and 750 nm. Similarly, where the first and second semiconductor layers 202 and 204 comprise GaAs, the refractive index of GaAs is about 3.5 for light wavelengths between 380 nm and 750 nm.

This mismatch between the refractive indices at the boundary of the transparent bonding layer 208 and the transparent substrate 210 with the first semiconductor layer 202 will result in the total internal reflection of some of the photons emitted by the light emitting layer 206 that have an angle of incidence that is larger than the critical angle Θ_{c}. Roughening the surface of the first semiconductor layer 202 adjacent the transparent bonding layer 208 increases the likelihood of the photons emitted by the light emitting layer 206 will escape the LED 216 by increasing the surface area between the first semiconductor layer 202 and transparent bonding layer 208, and allowing photons to bounce back-and-forth within a given projection until it is able to escape. Roughening the surface of the first semiconductor layer 202 thereby improves the light output power and light extraction efficiency of the surface-mountable LED assembly 200.

In one embodiment, at least a portion of the surface of the first semiconductor layer 202 adjacent the transparent bonding layer 208 is roughened. In another embodiment, the entire surface of the first semiconductor layer 202 is roughened. The projections formed as a result of roughening the surface of the first semiconductor layer 202 can be any suitable shape including, for example, a cone or a pyramid. In other embodiments, where the refractive index of the transparent bonding layer 208 and the transparent substrate 210 are substantially similar to the refractive index of the first and second semiconductor layers 202 and 204, it is not necessary to roughen the surface of the first semiconductor layer 202 as the incidence of total internal reflection is minimized. To further improve the light extraction efficiency of the LED assembly 200, the side walls of the transparent substrate 210 may be shaped so as to avoid photons from being trapped in the transparent substrate 210.

As previously discussed, by bonding the transparent substrate 210 to the first semiconductor layer 202 of the LED with the transparent bonding layer 208, the choice of material comprising the transparent substrate 210 is greatly expanded and is not limited to transparent and mono-crystalline materials such SiC or Al₂O₃ as is the case with conventional surface-mountable LED assemblies such as the one shown in FIG. 1. This results in a surface-mountable LED assembly 200 that has similar light output power, light extraction efficiency, and overall device performance as conventional surface-mountable LED assemblies, but at significant reduced cost to produce.

FIG. 3 shows a cross-sectional view of a surface-mountable LED assembly 300, according to another embodiment of the invention. As shown in FIG. 3, like the surface-mountable LED assembly 200 of FIG. 2, the surface-mountable LED assembly 300 comprises an LED 320 comprising a first semiconductor layer 302, a second semiconductor layer 304, and a light emitting layer 306 disposed between the first and second semiconductor layers 302 and 304. A first electrode 314 is formed adjacent a surface of the first semiconductor layer 302, and is electrically coupled to the first semiconductor layer 302. A second electrode 312 is formed adjacent a surface of the second semiconductor layer 304, and is electrically coupled to the second semiconductor layer 304. A transparent substrate 310 is bonded to a roughened surface of the first semiconductor layer 302 of the LED 320 via a transparent bonding layer 308. The materials and properties of the first and second semiconductor layers 302 and 304, the first and second electrodes 314 and 312, the transparent substrate 310, and the transparent bonding layer 308 are substantially similar to their corresponding elements described in connection with the surface-mountable LED assembly 200 shown in FIG. 2.

The surface-mountable LED assembly 300 further includes a layer 316 doped with a light wavelength-converting material 318. In one embodiment, the layer 316 comprises silicone. The light wavelength-converting material 318 converts a wavelength of the photons that strike the light wavelength-converting material 318 to a different (typically longer) wavelength, effectively changing the color of the emitted photon. Depending on the type of light wavelength-converting material 318 used to dope the layer 316, the surface-mountable LED assembly 300 may emit various colors of light different from the light that is naturally emitted by the light emitting layer 306.

For example, where the first and second semiconductor layers 302 and 304 comprise GaN, the color of the light emitted by the light emitting layer 306 is generally perceived to be blue. Depending on the end-application of the surface-mountable LED assembly 300, blue light may or may not be suitable. For example, in most domestic home lighting applications, white light is preferred. Thus, to emit white light where the first and second semiconductor layers 302 and 304 of the LED 320 comprises GaN, the light wavelength-converting material 318 comprises a material that changes the wavelength from the emitted photons that strike the light wavelength-converting material 318 from about 450-460 nm (blue) to about 570-590 nm (yellow).

Only a portion of the photons emitted from the light emitting layer 306 will strike the light wavelength-converting material 318 as they pass through the layer 316, resulting in both blue and yellow light being emitted by the surface-mountable LED assembly 300. The combination of the light wavelengths of the blue and yellow light results in white light. Further, the recipe of light wavelength-converting material 318 can be varied to fine-tune the shade of white light emitted by the surface-mountable LED assembly 300. For example, adding an appropriate amount of light wavelength-converting material 318 that changes the wavelength from the emitted photons to green, red, and yellow will result in a shift in the correlated color temperature (CCT) of the white light that is generated as a result of mixing green, red, and yellow light, providing for what is generally described as “natural” or “warm” white light (similar to that of a traditional filament-based light bulb) being emitted from the surface-mountable LED assembly 300.

Typically, depending on the thickness of the layer 316, the layer 316 may be doped with an amount of the light-wavelength converting material 318 anywhere from a few weight percent (wt. %) to 80-90 wt. %, depending on the desired color temperature. In one embodiment, the light-wavelength converting material 318 comprises phosphor particles. In other embodiments, the light-wavelength converting material 318 may comprise nanostructures, such as nanowires, or quantum dots. The addition of the layer 316 doped with light wavelength-converting material 318 allows for the surface-mountable LED assembly 300 to produce any color light within the visible spectrum regardless of the semiconductor material used to form the first and second semiconductor layers 302 and 304 of the LED, further enhancing the flexibility regarding the selection of materials used to produce the surface-mountable LED assembly 300.

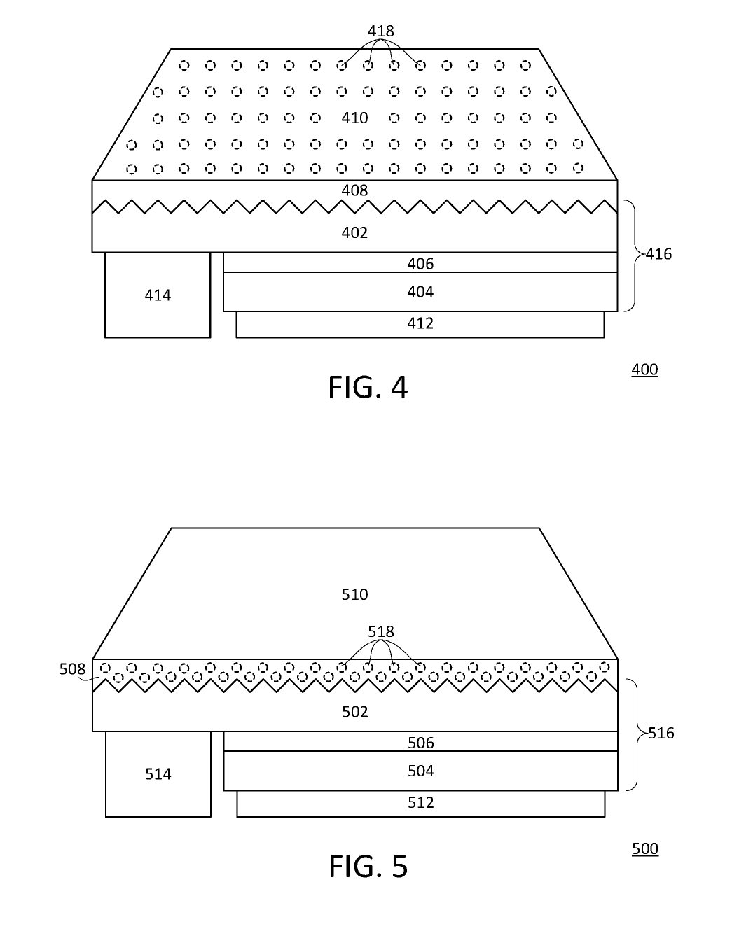

FIG. 4 shows a cross-sectional view of a surface-mountable LED assembly 400, according to yet another embodiment of the invention. The surface-mountable LED assembly 400 comprises an LED 416 comprising a first semiconductor layer 402, a second semiconductor layer 404, and a light emitting layer 406 disposed between the first and second semiconductor layers 402 and 404. A first electrode 414 is formed adjacent a surface of the first semiconductor layer 402, and is electrically coupled to the first semiconductor layer 402. A second electrode 412 is formed adjacent a surface of the second semiconductor layer 404, and is electrically coupled to the second semiconductor layer 404. A transparent substrate 410 is bonded to a roughened surface of the first semiconductor layer 402 of the LED 416 via a transparent bonding layer 408. The materials and properties of the first and second semiconductor layers 402 and 404, the first and second electrodes 414 and 412, the transparent substrate 410, and the transparent bonding layer 408 are substantially similar to their corresponding elements described in connection with the surface-mountable LED assembly 200 shown in FIG. 2.

Here the transparent substrate 410 of the surface-mountable LED assembly 400 is an amorphous solid, not a mono-crystalline structure. The transparent substrate 410 is doped with a light wavelength-converting material 418. Similar to the layer 316 as shown and described in FIG. 3, the transparent substrate 410 may be doped with the light wavelength-converting material 418 anywhere from a few wt. % to 80-90 wt. %, depending on the desired color temperature of the surface-mountable LED assembly 400. In one embodiment, the light wavelength-converting material 418 comprises phosphor particles. In other embodiments, the light wavelength-converting material 418 may comprise nanostructures, such as nanowires, or quantum dots.

By doping the transparent substrate 410 with the light wavelength-converting material 418, the surface-mountable LED assembly 400 realizes a number of advantages compared to the surface-mountable LED assembly 300 shown and described in connection with FIG. 3. In terms of cost, doping the transparent substrate 410 with the light wavelength-converting material 418 saves the extra manufacturing steps and corresponding cost required to deposit an additional layer of material over the transparent substrate 418, as is the case with the surface-mountable LED assembly 300 shown in FIG. 3.

In terms of performance, the surface-mountable LED assembly 400 will be able to operate at higher power as compared to the surface-mountable LED assembly 300. Typically, light wavelength-converting material 418, such as phosphor particles, generate heat when struck by photons. By doping the transparent substrate 410 with the light wavelength-converting material 418, rather than disposing an additional layer doped with a light wavelength-converting material, such as in FIG. 3, the heat generated by the light wavelength-converting material 418 has a shorter thermal pathway—and correspondingly less thermal resistance—down to the first and second electrodes 414 and 412 which are typically connected to a package or printed circuit board (PCB) submount that acts as a heatsink for the surface-mountable LED assembly 400.

The heat generated from the phosphor particles 418 closest to the transparent bonding layer 408 will only have to travel a short distance, through the transparent bonding layer 408 and the LED 416 to reach the first and second electrodes 414 and 412. However, the thermal pathway for the heat generated by the phosphor particles 418 closest to the outer edge of the transparent substrate 410 still has a comparatively shorter thermal pathway as compared to the phosphor particles 318 in the layer 316 above the transparent substrate 310, as shown in FIG. 3. A comparatively shorter thermal pathway and lower thermal resistance simultaneously allows the surface-mountable LED assembly 400 to be operated at higher power while improving device reliability due to reduced thermal stress on the LED.

Moreover, the layer 316 disposed over the surface-mountable LED assembly 300 shown in FIG. 3 may comprises silicone or a silicone-based material, which tends to degrade at temperatures above 200° C. The transparent substrate 410 has no such limitation. For example glass will remain transparent at temperatures significantly above 200° C. As such, the surface-mountable LED assembly 400 is suitable for end-applications requiring operation at high power and high temperatures while maintaining the ability to emit light in the various colors of the visible light spectrum.

FIG. 5 shows a cross-sectional view of a surface-mountable LED assembly 500, according to yet another embodiment of the invention. Again, the surface-mountable LED assembly 500 comprises an LED 516 comprising a first semiconductor layer 502, a second semiconductor layer 504, and a light emitting layer 506 disposed between the first and second semiconductor layers 502 and 504. A first electrode 514 is formed adjacent a surface of the first semiconductor layer 502, and is electrically coupled to the first semiconductor layer 502. A second electrode 512 is formed adjacent a surface of the second semiconductor layer 504, and is electrically coupled to the second semiconductor layer 504. A transparent substrate 510 is bonded to a roughened surface of the first semiconductor layer 502 of the LED 516 via a transparent bonding layer 508. The materials and properties of the first and second semiconductor layers 502 and 504, the first and second electrodes 514 and 512, the transparent substrate 510, and the transparent bonding layer 508 are substantially similar to their corresponding elements described in connection with the surface-mountable LED assembly 200 shown in FIG. 2.

In this embodiment, the transparent bonding layer 508 is doped with a light wavelength-converting material 518. The transparent substrate 510 may be doped with the light wavelength-converting material 518 anywhere from a few wt. % to 80-90 wt. %, depending on the desired color temperature of the surface-mountable LED assembly 500. In one embodiment, the light-wavelength converting material 518 comprises phosphor particles. In other embodiments, the light wavelength-converting material 518 may comprise nanostructures, such as nanowires, or quantum dots.

Similar to the transparent substrate 410 doped with the light wavelength-converting material 418 of the surface-mountable LED assembly 400 shown in FIG. 4, doping the transparent bonding layer 508 with the light wavelength-converting material 518 will result in fewer steps to manufacture the surface-mountable LED assembly 500, and can be operated at high power and temperature. Moreover, the surface-mountable LED assembly 500 will have even better thermal characteristics compared to the surface mountable LED assembly 400 because the heat generated by photons striking the light wavelength-converting material 518 has an even shorter thermal path (from the transparent bonding layer 508 compared to the transparent substrate 510) to reach the first and second electrodes 514 and 512, and subsequently the package or PCB submount which acts as the heatsink for the surface-mountable LED assembly 500.

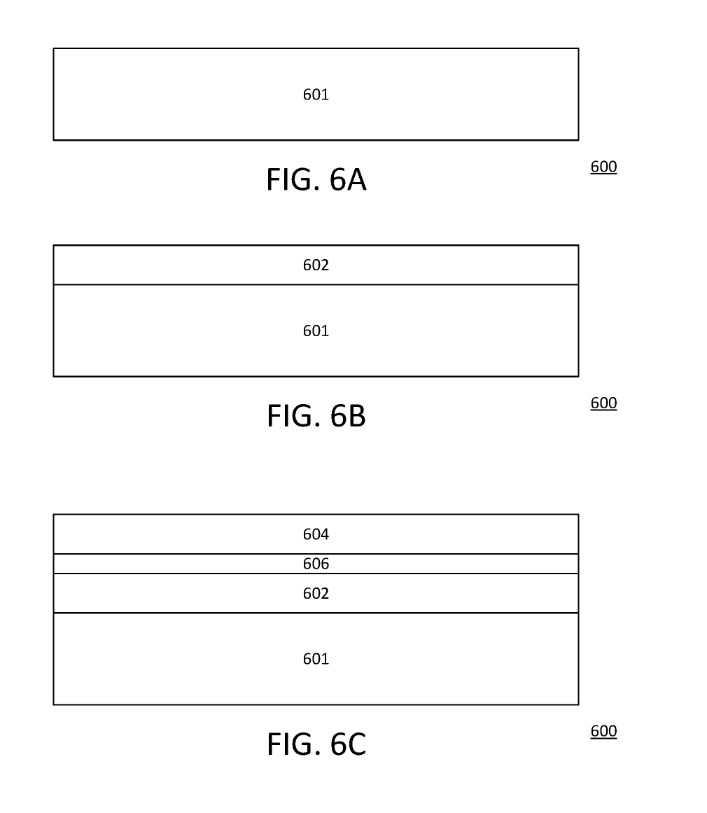

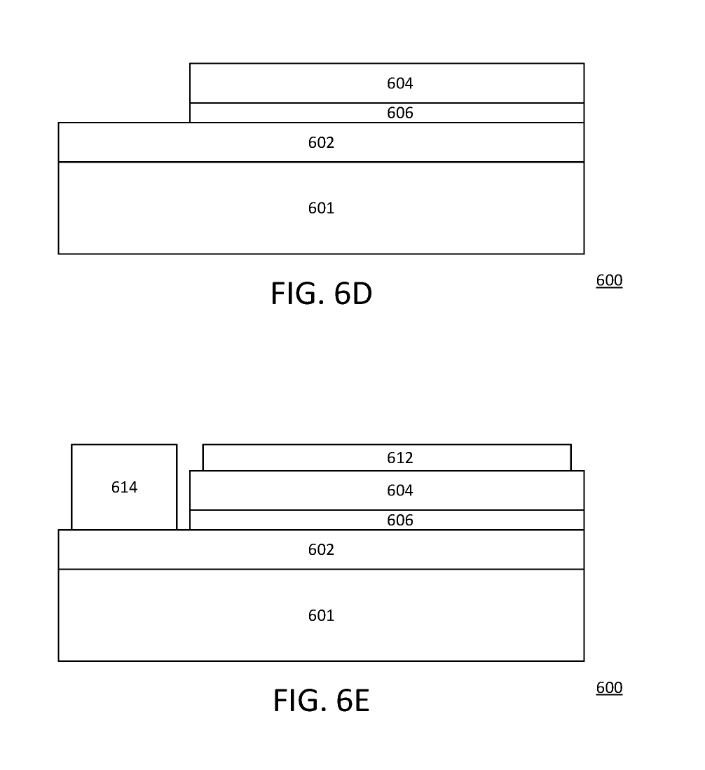

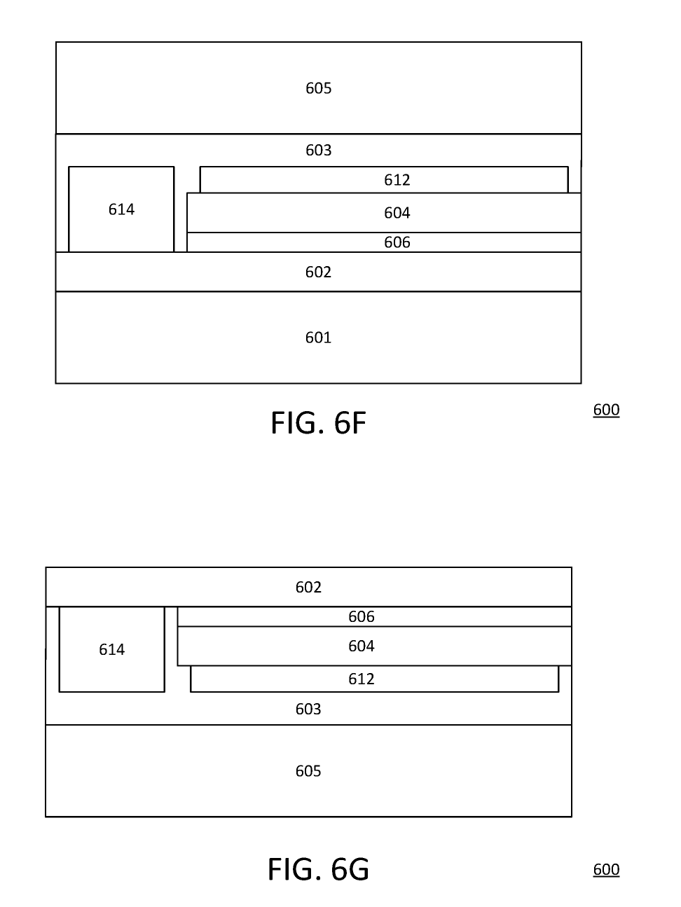

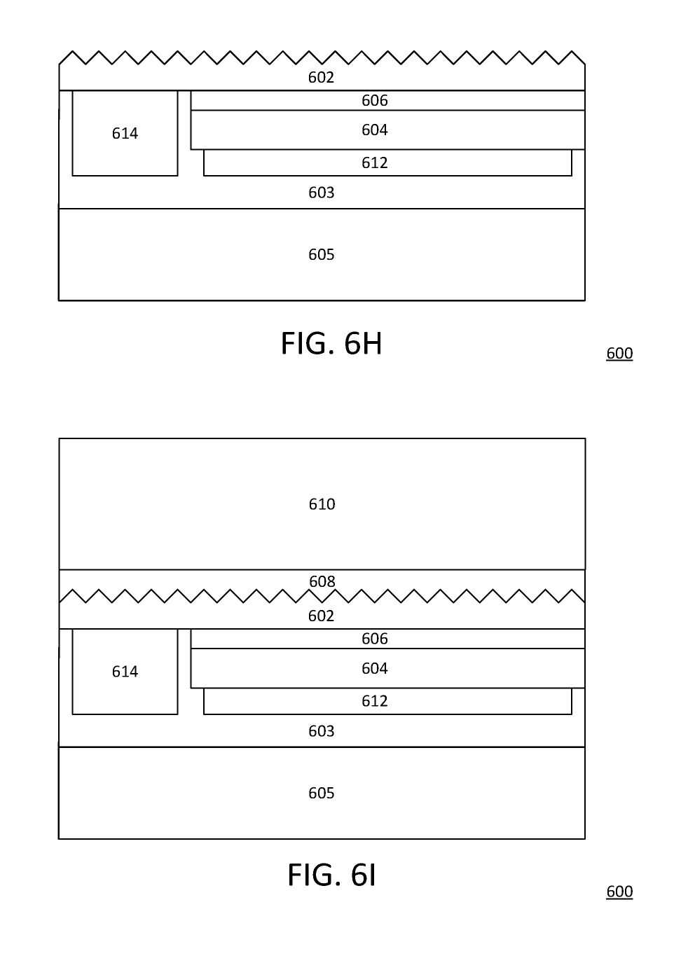

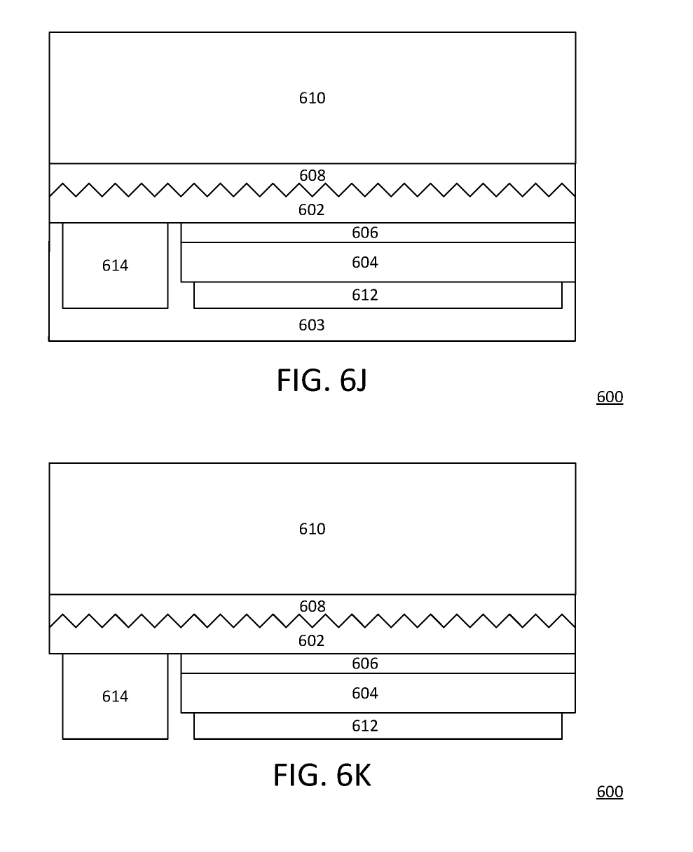

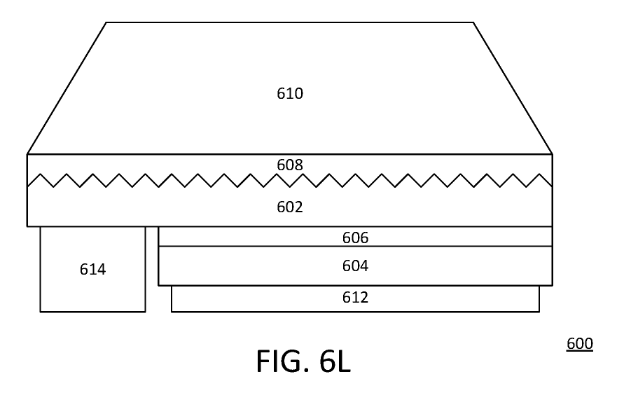

FIGS. 6A-6L shows cross-sectional views of the manufacturing steps for producing a surface-mountable LED assembly, according to one embodiment of the invention. In FIG. 6A, a growth substrate 601 is provided. Growth substrate 601 is typically a wafer, and may comprise any material suitable for epitaxially growing layers of group III-V compounds, or in another embodiment, group II-VI compounds. In one embodiment, growth substrate 601 comprises Si. In other embodiments, growth substrate 601 may comprise GaAs, GaP, InP, GaAsP, Al₂O₃, SiC, or bulk GaN.

In FIG. 6B, a first semiconductor layer 602 is epitaxially grown on a surface of the growth substrate 601. In one embodiment, the first semiconductor layer 602 comprises a group III-V compound, such as GaN, GaAs, GaP, InP, or GaAsP. In another embodiment, the first semiconductor layer 602 comprises a group II-VI compound. In one embodiment, the first semiconductor layer 602 comprises an N-type semiconductor material. In another embodiment, the first semiconductor layer 602 comprises a P-type semiconductor material. The first semiconductor layer 602 may be grown using any known growth method, including MOCVD, MBE, LPE, or vapor phase epitaxy (VPE).

In FIG. 6C, a second semiconductor layer 604 is epitaxially grown on top of the first semiconductor layer 602. The second semiconductor layer 604 comprises the same semiconductor material as the first semiconductor layer 602 and having a conductivity type opposite that of the first semiconductor layer 602. For example, in one embodiment, the first semiconductor layer 602 comprises an N-type semiconductor material and the second semiconductor layer 604 comprises a P-type semiconductor material. In another embodiment, the first semiconductor layer 602 comprises a P-type semiconductor material and the second semiconductor layer 604 comprises an N-type semiconductor material. For example, in one embodiment, the first semiconductor layer 602 comprises N-type GaN and the second semiconductor layer 604 comprises P-type GaN. A light emitting layer 606 is formed at the interface of the first and second semiconductor layers 602 and 604. The first semiconductor layer 602, the light emitting layer 606, and the second semiconductor layer 604 comprises an LED.

In FIG. 6D, a portion of the second semiconductor layer 604 and light emitting layer 606 is removed, exposing a surface of the first semiconductor layer 602 opposite the growth substrate 601. The portion of the second semiconductor layer 604 and the light emitting layer 606 may be removed using any suitable process, including known photolithography and etching processes.

In FIG. 6E, a first electrode 614 is deposited on a portion of the exposed surface of the first semiconductor layer 602 and electrically coupled to the first semiconductor layer 602, and a second electrode 612 is deposited on a surface of the second semiconductor layer 604 and electrically coupled to the second semiconductor layer 604. The first and second electrodes 614 and 612 may be formed using any suitable process, including known photolithography, etching, evaporation, and polishing processes. The first and second electrodes 614 and 612 preferably comprise a material having a high degree of optical reflectivity, such as Al, Au, Rh, and/or Ag.

In FIG. 6F, a temporary handling substrate 605 is bonded to the first and second semiconductor layers 602 and 604, and the first and second electrodes 614 and 612 via a temporary bonding layer 603. Temporary handing substrate 605 may be any material suitable for providing structural rigidity, provided that the material is chemically resistant and is capable of withstanding temperatures above 300° C. as the material will be subjected to further treatment in subsequent manufacturing steps. Similarly, temporary bonding layer 603 may comprise any suitable material for bonding the temporary handling substrate 605, provided that the material is chemically resistant and is capable of withstanding temperatures above 300° C. without de-bonding. For example, in one embodiment, the temporary bonding layer 603 may comprise a siloxane-based polymer.

In FIG. 6G, the growth substrate 601 is removed. Growth substrate 601 may be removed using any known process, including chemical etching, mechanical grinding, laser lift-off (LLO), or any combination of processes.

In FIG. 6H, a surface of the first semiconductor layer 602 that is exposed after removal of the growth substrate 601 is roughened, forming a plurality of projections having peaks and valleys. In one embodiment, at least a portion of the surface of the first semiconductor layer 602 is roughened. In another embodiment, the entire surface of the first semiconductor layer 602 is roughened. As previously discussed, the projections increase the likelihood for photons emitted by the light emitting layer 606 to escape the completed surface-mountable LED assembly 600. The surface of the first semiconductor layer 602 may be roughened using any known process, including wet chemical etching or dry etching. The projections formed as a result of roughening the surface of the first semiconductor layer 602 can be any suitable shape including, for example, a cone or a pyramid.

In other embodiments, where the refractive index of the first and second semiconductor layers 602 and 604 are substantially similar to the refractive index of the transparent bonding layer and transparent substrate, it is not necessary for the surface of the first semiconductor layer 602 to be roughened because the likelihood of total internal reflection is low.

In FIG. 6I, a transparent substrate 610 is bonded to the first semiconductor layer 602 of the LED via a transparent bonding layer 608. In one embodiment, the transparent substrate 610 and the transparent bonding layer 608 transmit visible light. In other embodiments, the transparent substrate 610 and the transparent bonding layer 608 may transmit UV light or IR light. In various embodiments, the transparent substrate 610 and transparent bonding layer 608 has a transmittance greater than 50% for light wavelengths falling within the desired transmitted light spectrum (e.g. visible light, UV light, or IR light). In one embodiment, the transparent substrate 610 is monolithic.

The transparent substrate 610 may comprise an amorphous solid, such as glass. The transparent bonding layer 608 may be any suitable material that is capable of bonding the transparent substrate 610 to the first semiconductor layer 602 of the LED. In one embodiment, the transparent bonding layer 608 comprises a silicone-based bonding material. In other embodiments, the transparent bonding layer 608 may comprise an epoxy-based bonding material or SOG.

Optionally, to form the surface-mountable LED assembly 400 shown and described in connection with FIG. 4, the transparent substrate 610 may be doped with a light wavelength-converting material, such as phosphor particles, nanostructures (such as nanowires), or quantum dots, prior to bonding. Similarly, to form the surface-mountable LED assembly 500 shown and described in connection with FIG. 5, the transparent bonding layer 608 may be doped with a light wavelength-converting material, such as phosphor particles, nanostructures (such as nanowires), or quantum dots, prior to bonding. The transparent substrate 610 and/or the transparent bonding layer 608 may be doped with the light wavelength-converting material anywhere from a few wt. % to 80-90 wt. %, depending on the desired color temperature of the completed surface-mountable LED assembly 600.

In FIG. 6J, the temporary handling substrate 605 is removed. Temporary handling substrate 605 is no longer necessary because the transparent substrate 610 provides structural support for the first and second semiconductor layers 602 and 604. Temporary handling substrate 605 may be removed using a mechanical de-bonding process, such as inserting a knife edge where the temporary handling substrate 605 meets the temporary bonding layer 603. The temporary bonding layer 603 delaminates under the localized mechanical stress exerted by the knife edge. In FIG. 6K, the residual temporary bonding layer 603 is cleaned off the first and second semiconductor layers 602 and 604, and the first and second electrodes 614 and 612.

In FIG. 6L, individual surface-mountable LED assembly 600 are singulated from adjacent devices using known dicing techniques, including mechanical, laser, or chemical processes. The surface-mountable LED assembly 600 shown in FIG. 6L is substantially similar to the surface-mountable LED assembly 200 shown and described in connection with FIG. 2, according to one embodiment of the invention.

Optionally, to form the surface-mountable LED assembly 300 shown and described in connection with FIG. 3 according to one embodiment of the invention, a layer doped with a light wavelength-converting material may be disposed over the surface of the transparent substrate 610 opposite the LED. In one embodiment, the layer comprises silicone. In one embodiment the light wavelength-converting material comprises phosphor particles. In other embodiments, the light wavelength-converting material comprises nanostructures, such as nanowires, or quantum dots.

Other objects, advantages and embodiments of the various aspects of the present invention will be apparent to those who are skilled in the field of the invention and are within the scope of the description and the accompanying Figures. For example, but without limitation, structural or functional elements might be rearranged, or method steps reordered, consistent with the present invention. Similarly, principles according to the present invention could be applied to other examples, which, even if not specifically described here in detail, would nevertheless be within the scope of the present invention.

What is claimed is:

1. A surface-mountable light emitting diode (LED) assembly comprising:
an LED comprising a first layer having a first conductivity type, a second layer having a second conductivity type, and a light emitting layer disposed between the first layer and the second layer;
a transparent substrate bonded to the LED via a transparent bonding layer disposed between the transparent substrate and the LED;
a first electrode disposed on a surface of the first layer opposite the transparent substrate and electrically coupled to the first layer; and
a second electrode disposed on a surface of the second layer opposite the transparent substrate and electrically coupled to the second layer.

2. The surface-mountable LED assembly of claim 1, wherein the transparent substrate is monolithic.

3. The surface-mountable LED assembly of claim 1, wherein the transparent substrate passes light wavelengths between 380 nm and 750 nm.

4. The surface-mountable LED assembly of claim 3, wherein the transparent substrate has a transmittance greater than 50% for light wavelengths between 380 nm and 750 nm.

5. The surface-mountable LED assembly of claim 1, wherein the transparent bonding layer passes light wavelengths between 380 nm and 750 nm.

6. The surface-mountable LED assembly of claim 5, wherein the transparent bonding layer has a transmittance greater than 50% for light wavelengths between 380 nm and 750 nm.

7. The surface-mountable LED assembly of claim 1, further comprising:
a layer doped with a light wavelength-converting material, wherein the layer is disposed over a surface of the transparent substrate opposite the LED.

8. The surface-mountable LED assembly of claim 1, wherein the transparent substrate is doped with a light wavelength-converting material.

9. The surface-mountable LED assembly of claim 1, wherein the transparent bonding layer is doped with a light wavelength-converting material.

10. The surface-mountable LED assembly of claim 7, wherein the light wavelength-converting material comprises a material selected from the group consisting of phosphor particles, quantum dots, and nanostructures.

11. The surface-mountable LED assembly of claim 8, wherein the light wavelength-converting material comprises a material selected from the group consisting of phosphor particles, quantum dots, and nanostructures.

12. The surface-mountable LED assembly of claim 9, wherein the light wavelength-converting material comprises a material selected from the group consisting of phosphor particles, quantum dots, and nanostructures.

13. The surface-mountable LED assembly of claim 1, wherein at least a portion of a surface of the first layer adjacent the transparent bonding layer is roughened.

14. The surface-mountable LED assembly of claim 1, wherein the transparent substrate comprises an amorphous solid.

15. The surface-mountable LED assembly of claim 1, wherein the transparent substrate comprises glass.

16. The surface-mountable LED assembly of claim 1, wherein the transparent bonding layer comprises a silicone-based material.

17. The surface-mountable LED assembly of claim 1, wherein the transparent bonding layer comprises an epoxy-based material.

18. The surface-mountable LED assembly of claim 1, wherein the transparent bonding layer comprises spin-on glass (SOG).

19. The surface-mountable LED assembly of claim 1, wherein the transparent substrate has a refractive index between 1.4 and 1.7 for light wavelengths between 380 nm and 750 nm.

20. The surface-mountable LED assembly of claim 1, wherein the transparent bonding layer has a refractive index between 1.4 and 1.7 for light wavelengths between 380 nm and 750 nm.

21. The surface-mountable LED assembly of claim 1, wherein the first layer and the second layer comprise a group III-V compound.

22. The surface-mountable LED assembly of claim 1, wherein the first layer and the second layer comprises a material selected from the group consisting of GaN, AlGaN, InAlN, AlInGaN, GaAs, GaP, and InP.

23. A method of forming a surface-mountable light emitting diode (LED) assembly, the method comprising:
providing a growth substrate;
forming an LED comprising a light emitting layer disposed between a first layer having a first conductivity type and a second layer having a second conductivity type on a surface of the growth substrate;
forming a first electrode on a surface of the first layer and electrically coupled to the first layer;
forming a second electrode on a surface of the second layer and electrically coupled to the second layer;
bonding a temporary handling substrate to the LED via a temporary bonding layer between the temporary handling substrate and the LED;
removing the growth substrate;
bonding a transparent handing substrate to the LED via a transparent bonding layer disposed between the transparent substrate and the LED; and
removing the temporary handling substrate and the temporary bonding layer.
